(19) United States
(12) Patent Application Publication
(10) Pub. No.: US 2009/0071683 A1
(43) Pub. Date: Mar. 19, 2009

(54) ELECTRONIC DEVICE MOUNTING STRUCTURE AND METHOD OF MAKING THE SAME

(75) Inventors: Akio Yasuda, Kosai-city (JP); Mutsumi Yoshino, Nagoya-city (JP)

Correspondence Address: NIXON & VANDERHYE, PC, 901 NORTH GLEBE ROAD, 11TH FLOOR, ARLINGTON, VA, 22203, US

(73) Assignee: DENSO CORPORATION, Kariya-city (JP)

(21) Appl. No.: 12/209,513

(22) Filed: Sep. 12, 2008

(30) Foreign Application Priority Data
Sep. 13, 2007 (JP) 2007-238524

(51) Int. Cl. H02G 5/00; H01R 43/00

(52) U.S. Cl. 174/68.2; 29/825

(57) ABSTRACT

An electronic device mounting structure includes a printed circuit board, a busbar, and an electronic device mounted on the busbar. The busbar includes a parallel portion extending parallel to the printed circuit board and a bent portion extending from the parallel portion toward the printed circuit board. The bent portion of the busbar includes a first bent portion, a second bent portion, and a tip portion A thickness direction of the first bent portion is substantially parallel to a length direction of the parallel portion A thickness direction of the second bent portion is substantially parallel to a width direction of the parallel portion. The tip portion stands substantially at a right angle with respect to the second bent portion and is soldered to the printed circuit board.

### CROSS REFERENCE TO RELATED APPLICATION

This application is based on and incorporates herein by reference Japanese Patent Application No. 2007-238524 filed on Sep. 13, 2007.

### FIELD OF THE INVENTION

The present invention relates to an electronic device mounting structure including a printed circuit board and a busbar located parallel to the printed circuit board and bent to be soldered to the printed circuit board, and also relates to a method of making the structure.

### BACKGROUND OF THE INVENTION

An electronic apparatus is constructed with various types of electronic devices. Typically, a low-power consumption device is mounted on a printed circuit board, and a high-power consumption device is mounted on a busbar.

As disclosed, for example, in JP-A-2002-93995, the printed circuit board and the busbar may be arranged parallel (i.e., overlap) to each other so that the electronic apparatus can be reduced in size. The busbar is fixed to a metal plate (i.e., heatsink) through an insulation film. An end portion of the busbar is bent toward the printed circuit board and joined to the printed circuit board through solder.

In the structure disclosed in JP-A-2002-93995, the solder joint between the busbar and the printed circuit board is subjected to thermal stress due to a difference in coefficients of linear (thermal) expansion between the busbar and the printed circuit board. For example, when a temperature becomes high due to, for example, heat generated by the high-power consumption device mounted on the busbar, the busbar expands in its length and width directions. As a result, the printed circuit board is pulled in its surface direction (i.e., the length and width directions of the busbar), and thermal stress is applied to the solder joint between the busbar and the printed circuit board in the surface direction of the printed circuit board. In this way, the thermal stress is repeatedly applied to the solder joint during use. The repeated thermal stress may degrade the solder joint.

### SUMMARY OF THE INVENTION

In view of the above-described problem, it is an object of the present invention to provide an electronic device mounting structure for reducing thermal stress applied to a solder joint between a busbar and a printed circuit board in a surface direction of the printed circuit board. It is another object of the present invention to provide a method of making the structure.

According to an aspect of the present invention, an electronic device mounting structure includes a printed circuit board, a busbar, an electronic device, and a metal plate. The busbar includes a parallel portion extending parallel to the printed circuit board and a bent portion extending from a first end of the parallel portion toward the printed circuit board. The parallel portion has a length in a first direction and a width in a second direction perpendicular to the first direction. The electronic device is fixed to the busbar and has a terminal soldered to a second end of the parallel portion of the busbar. The busbar is fixed on the metal plate and electrically insulated from the metal plate. The metal plate has a linear expansion coefficient greater than or equal to a linear expansion coefficient of the busbar. The bent portion of the busbar includes a first bent portion extending from the parallel portion, a second bent portion extending from the first bent portion, and a tip portion extending from the second bent portion. The first bent portion has a thickness substantially in the first direction. The second bent portion has a thickness substantially in the second direction. The tip portion stands substantially at a right angle with respect to the second bent portion and is soldered to the printed circuit board.

According to another aspect of the present invention, a method of making the structure includes forming a plurality of busbar bases connected together through tie-bars from a metal sheet by press punching. The busbar bases includes a plurality of parallel portions arranged parallel to each other and a plurality of developed bent portions, each of which is joined to a corresponding parallel portion. The method further includes separating the busbar bases from each other by cutting the tie-bars and bending the developed bent portion of the separated busbar base to form the first and second bent portions.

### BRIEF DESCRIPTION OF THE DRAWINGS

The above and other objectives, features and advantages of the present invention will become more apparent from the following detailed description made with check to the accompanying drawings. In the drawings:

FIG. 1 is a diagram illustrating a cross-sectional view of an electronic device mounting structure according to a first embodiment of the present invention;

FIG. 2 is a diagram illustrating a perspective view of a busbar and a printed circuit board of the electronic device mounting structure of FIG. 1;

FIG. 3 is a diagram illustrating a perspective view of a bent portion of the busbar of FIG. 2;

FIG. 4 is a diagram illustrating a developed view of the bent portion of FIG. 3;

FIG. 5 is a diagram illustrating a front view of the bent portion of FIG. 3;

FIG. 6 is a diagram illustrating a top view of the bent portion of FIG. 3;

FIG. 7 is a diagram illustrating a developed view of a bent portion according to a second embodiment of the present invention;

FIG. 8 is a diagram illustrating a top view of the bent portion of FIG. 7;

FIG. 9 is a diagram illustrating a side view of the bent portion of FIG. 7;

FIG. 10 is a diagram illustrating a developed view of a bent portion according to a third embodiment of the present invention; and

FIG. 11 is a diagram illustrating a developed view of a bent portion according to a fourth embodiment of the present invention.

### DETAILED DESCRIPTION OF THE PREFERRED EMBODIMENTS

### First Embodiment

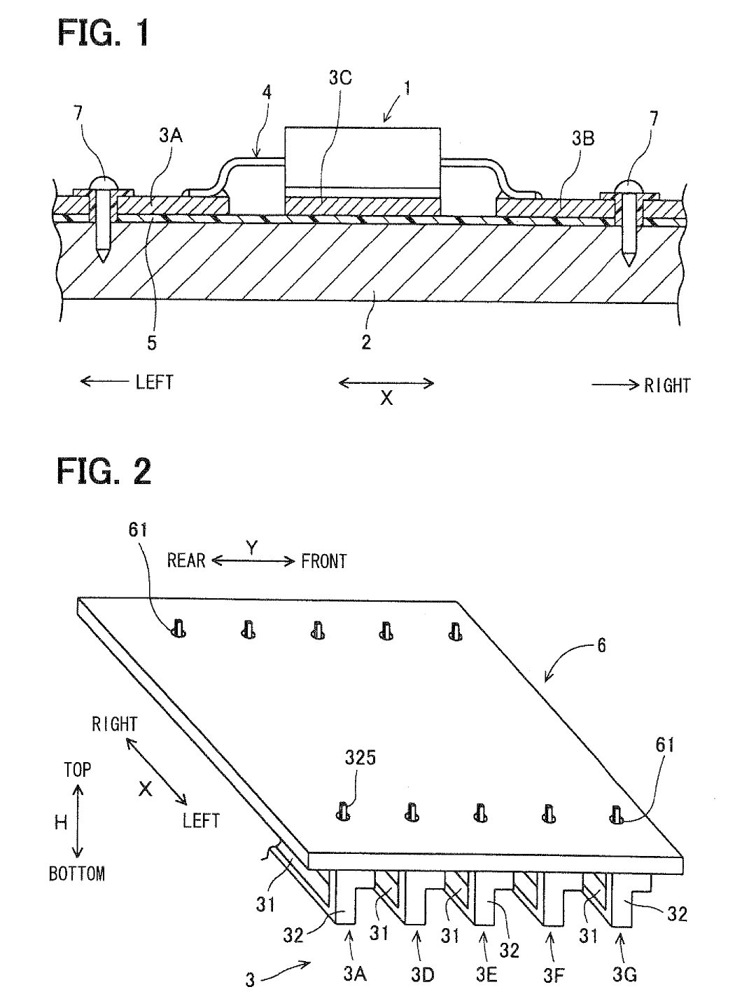

An electronic device mounting structure according to a first embodiment of the present invention is described below with reference to FIGS. 1-6. The structure includes an electronic device 1, a metal plate 2 serving as a heatsink, a busbar assembly 3, and an electrically insulation film 5 like a resin film, and a printed circuit board 6. The electronic device 1 is a resin-molded integrated circuit (IC) configured as a dual in-line package (DIP). The electronic device 1 has a body and lead terminals 4 protruding from either side of the body. The busbar assembly 3 includes a plurality of busbars 3A-3G. For example, the busbars 3A-3G and the lead terminals 4 can be made of copper.

As shown in FIG. 1, the busbar assembly 3 is placed on a top surface of the metal plate 2 through the insulation film 5. The electronic device 1 is joined to a top surface of the busbar 3C through adhesive, solder, or the like. The lead terminals 4 of the electronic device 1 are joined to the busbars 3A, 3C through solder. The busbars 3A-3C are fixed to the metal plate 2 by screws 9 in such a manner that the busbars 3A-3C can be electrically insulated from the metal plate 2. For example, each screw 9 is received in a resin sleeve.

As shown in FIG. 2, the printed circuit board 6 is located above the busbar assembly 3 and extends parallel to the metal plate 2. Since the busbar assembly 3 is placed on the metal plate 2, the printed circuit board 6 is located substantially parallel to the busbar assembly 3. A lot of low power consumption devices (not shown) are mounted on a top surface of the printed circuit board 6 and electrically connected together through trace patterns formed in the printed circuit board 6. Five receiving holes 61 are formed on each end of the printed circuit board 6 in a X-direction (left-right direction) and arranged in a line in a Y-direction (front-back direction). That is, the printed circuit board 6 has ten receiving holes 61 in total.

The busbars 3A, 3D-3G form a first busbar group located on the left end of the printed circuit board 6. The busbar 38 and other four busbars (not shown) form a second busbar group located on the right end of the printed circuit board 6. Each busbar of the first and second busbar groups has a parallel portion 31 extending in the X-direction and a bent portion 32 standing substantially at a right angle with respect to the parallel portion 31 and extending toward the printed circuit board 6. The parallel portion 31 has a first end soldered to the lead terminal 4 of the electronic device 1 and a second end joined to the bent portion 32. The bent portion 32 has a first end joined to the parallel portion 31 and a second end extending to the top in a H-direction and inserted into a corresponding receiving hole 61 of the printed circuit board 6.

For example, in the case of the busbar 3A, the parallel portion 31 extends to the left in the X-direction and is bent upwardly at a right angle to form the bent portion 32. The second end of the bent portion 32 of the busbar 3A is inserted in the receiving hole 61 of the printed circuit board 6 and soldered to a trace pattern formed around the receiving hole 61. Although not shown in the drawings, in the case of the busbar 3B, the parallel portion 31 extends to the right in the X-direction and is bent upwardly at a right angle to form the bent portion 32. The second end of the bent portion 32 of the busbar 3B is inserted in the receiving hole 61 of the printed circuit board 6 and soldered to a trace pattern formed around the receiving hole 61.

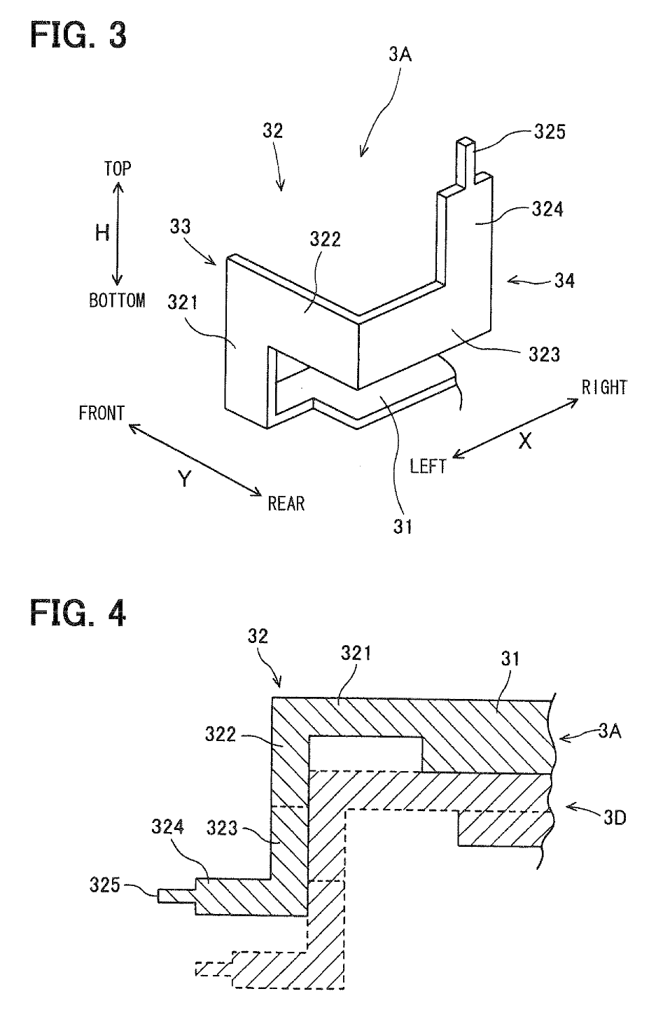

The bent portion 32 of the busbar 3A is illustrated in detail in FIG. 3. The bent portion 32 of each busbar of the first busbar group located on the left end of the printed circuit board 6 is configured in the same manner as the bent portion 32 of the busbar 3A. The bent portion 32 of each busbar of the second busbar group located on the right end of the printed circuit board 6 is configured in the reverse manner as the bent portion 32 of the busbar 3A.

The bent portion 32 of the busbar 3A includes a first projection 321 extending to the top in the H-direction at a right angle from the left end of the parallel portion 31, a second projection 322 extending to the back in the Y-direction from a tip of the first projection 321, a third projection 323 extending to the right in the X-direction from a tip of the second projection 322, a fourth projection 324 extending to the top in the H-direction from a tip of the third projection 323, and a terminal 325 extending to the top in the H-direction from a tip of the fourth projection 324. The terminal 325 is inserted in the receiving hole 61 of the printed circuit board 6. The projections 321, 322 have the same thickness in the X-direction and form a first bent portion 33. The projections 323, 324 have the same thickness in the Y-direction and form a second bent portion 34. The X-direction represents a length direction of the parallel portion 31, the Y-direction represents a width direction of the parallel portion 31, and the H-direction represents a thickness direction of the parallel portion 31. A surface direction of the printed circuit board 6 is substantially parallel to each of the X-direction and the Y-direction and is substantially perpendicular to the H-direction.

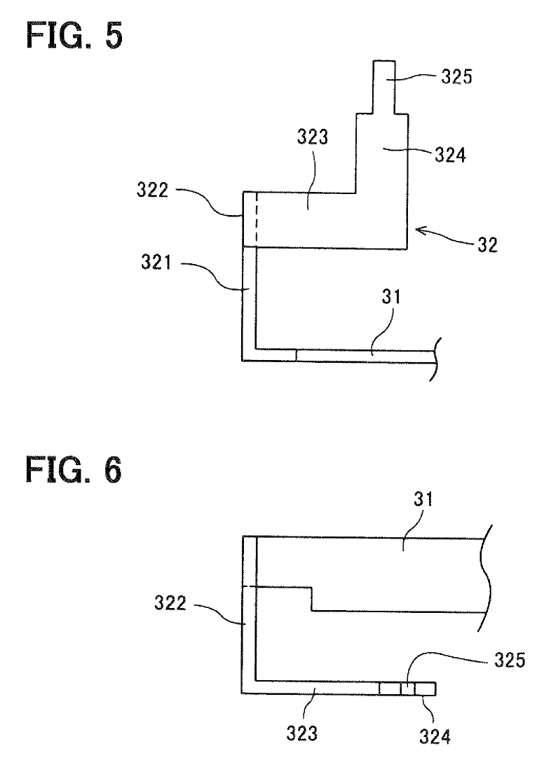

A method of making each busbar is described below with reference to FIGS. 4-6. FIG. 4 illustrates a developed shape of the busbars 3A, 3D. A base for the busbar assembly 3 including the busbars 3A, 3D is formed from a metal sheet (e.g., copper sheet) by press punching using a pattern shown in FIG. 4. The punched base includes basbar bases having the parallel portions 31 arranged parallel to each other and developed bent portions 32, each of which is joined to a corresponding parallel portion 31. As of this time, adjacent basbar bases are connected together through tie-bars (not shown). Then, the basbar bases are separated from each other by cutting the tie-bars, and each busbar base is fixed to the metal plate 2. Alternatively, the tie-bars can be cut after the basbar bases are collectively fixed to the metal plate 2. Then, the lead terminal 4 of the electronic device 1 is soldered to the parallel portion 31. Then, the developed bent portion 32 is bent so that the busbar can be shaped as shown in FIGS. 5, 6. FIG. 5 illustrates a front view of the busbar viewed from the back to the front in the Y-direction. FIG. 6 illustrates a top view of the busbar viewed from the top to the bottom in the H-direction.

The electronic device mounting structure according to the first embodiment can provide the following advantages.

When a temperature of the busbar assembly 3 becomes high due to, for example, heat generated by the electronic device 1, the busbar assembly 3 expands in the X-direction and the Y-direction. That is, the busbar assembly 3 expands in the surface direction of the printed circuit board 6. Typically, a linear (thermal) expansion coefficient of the busbar assembly 3 is greater than a linear expansion coefficient of the printed circuit board 6. Since the busbar assembly 3 is soldered to the printed circuit board 6, the printed circuit board 6 is pulled in the X-direction and the Y-direction as a result of the expansion of the busbar assembly 3. Further, the busbar assembly 3 is fixed to the metal plate 2, which generally has a linear expansion coefficient greater than that of the busbar assembly 3. Therefore, the expansion of the busbar assembly 3 is increased by the metal plate 2.

According to the first embodiment, the projections 321, 322 of the first bent portion 33 have the same thickness in the X-direction. Since the first bent portion 33 is thinnest in the X-direction, the first bent portion 33 can be easily deformed in the X-direction. That is, a relative displacement between a root of the projection 321 and the tip of the projection 322 in the X-direction can be easily achieved. Therefore, when the printed circuit board 6 is displaced with respect to the metal plate 2 and the busbar assembly 3 in the X-direction due to a difference in coefficients of linear expansions between the metal plate 2, the busbar assembly 3, and the printed circuit board 6, the first bent portion 33 can be deformed to absorb the relative displacement of the printed circuit board 6 with respect to the metal plate 2 and the busbar assembly 3 in the X-direction. Thus, thermal stress applied to a solder joint between the terminal 325 of each busbar and the receiving hole 61 of the printed circuit board 6 in the X-direction can be reduced. Also, thermal stress applied to a solder joint between the lead terminal 4 of electronic device 1 and each busbar in the X-direction can be reduced.

Likewise, the projections 323, 324 of the second bent portion 34 have the same thickness in the Y-direction. Since the second bent portion 34 is thinnest in the Y-direction, the second bent portion 34 can be easily deformed in the Y-direction. That is, a relative displacement between a root of the projection 323 and the tip of the projection 324 in the Y-direction can be easily achieved. Therefore, when the printed circuit board 6 is displaced with respect to the metal plate 2 and the busbar assembly 3 in the Y-direction due to a difference in coefficients of linear (thermal) expansions between the metal plate 2, the busbar assembly 3, and the printed circuit board 6, the second bent portion 34 can be deformed to absorb the relative displacement of the printed circuit board 6 with respect to the metal plate 2 and the busbar assembly 3 in the Y-direction. Thus, thermal stress applied to the solder joint between the terminal 325 of each busbar and the receiving hole 61 of the printed circuit board 6 in the Y-direction can be reduced. Also, thermal stress applied to the solder joint between the lead terminal 4 of electronic device 1 and each busbar in the Y-direction can be reduced.

In this way, the bent portion 32 of the first embodiment can reduce the thermal stress applied to the solder joints in the surface direction of the printed circuit board 6 so that the solder joints can be protected from repeated thermal stress.

### Second Embodiment

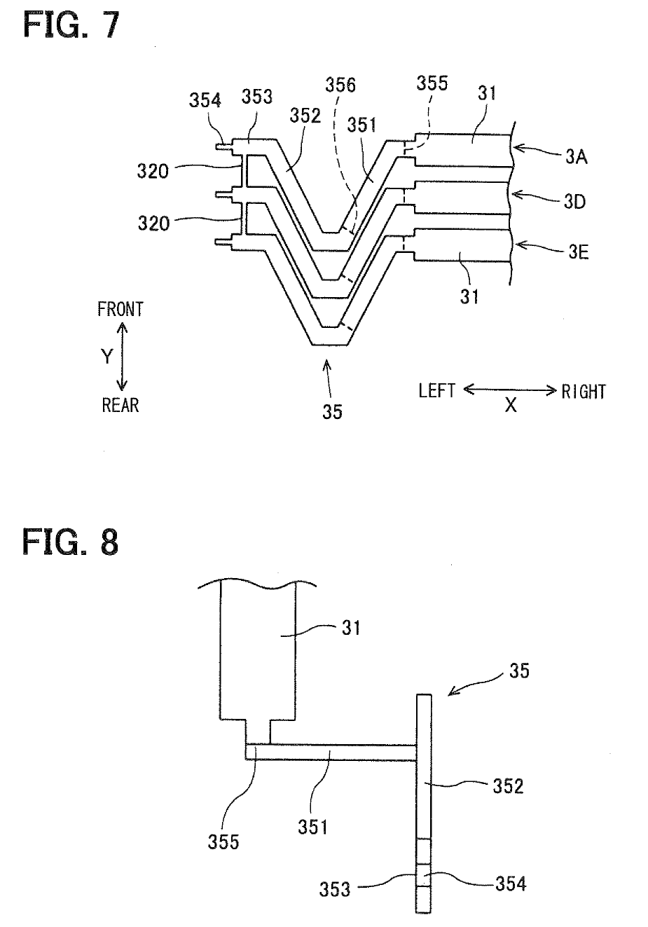

An electronic mounting structure according to a second embodiment of the present invention is described below with reference to FIGS. 7-9. A difference between the first and second embodiments is as follows.

FIG. 7 illustrates a developed shape of a bent portion 35 of each busbar 3A, 3D, 3E. In the developed shape, each bent portion 35 has a first bent portion 351 extending obliquely from the left end of the parallel portion 31, a second bent portion 352 extending obliquely from a tip of the first bent portion 351, a tip portion 353 extending approximately to the left from a tip of the second bent portion 352, and a terminal 354 extending approximately to the left from a tip of the tip portion 353. The terminal 354 is inserted in the receiving hole 61 of the printed circuit board 6. As can been seen from FIG. 7, the first and second bent portions 351, 352 extend in opposite directions to form an approximately V-shape.

The busbars 3A, 3D, 3E are arranged parallel to each other. The tip portions 353 of the busbars 3A, 3D, 3E are connected together through tie-bars 320 so that the busbars 3A, 3D, 3E can be joined together. A broken line 355 represents a border between the parallel portion 31 and the first bent portion 351, and a broken line 356 represents a border between first and second bent portions 351, 352.

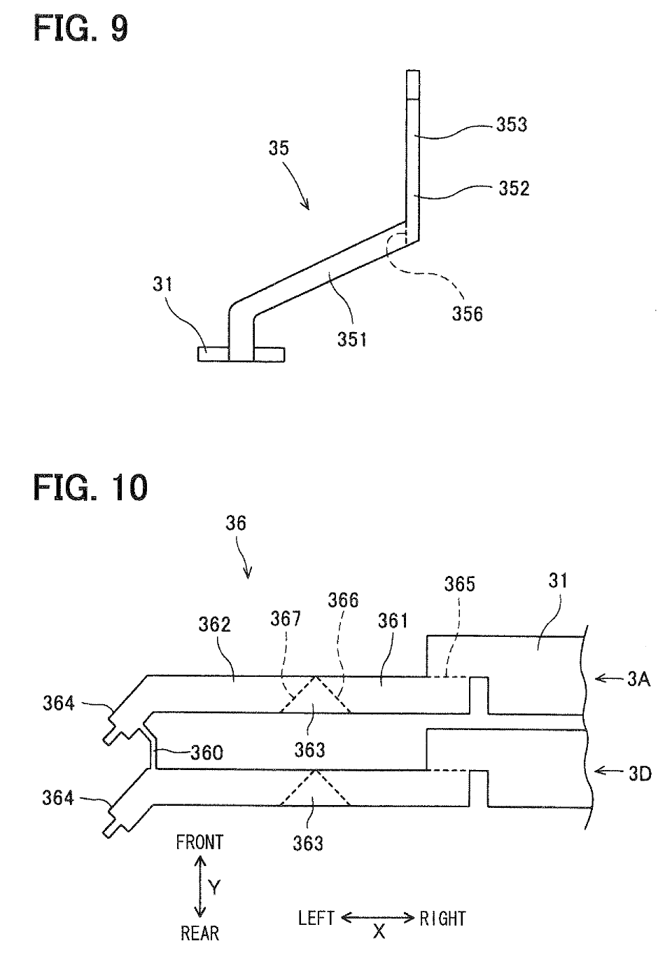

The bent portion 35 shown in FIG. 7 is bent along the broken lines 355, 356 so that the bent portion 35 shown in FIGS. 8, 9 can be obtained. FIG. 8 illustrates a top view of the bent portion 35 viewed from the top to the bottom in the H-direction. FIG. 9 illustrates a side view of the bent portion 35 viewed from the left to the right in the X-direction.

The first bent portion 351 stands obliquely from the left end of the parallel portion 31 in the width direction (i.e., Y-direction) of the parallel portion 31. Therefore, the first bent portion 351 has the thickness in the X-direction. The second bent portion 352 stands obliquely from the tip of the first bent portion 351 in the length direction (i.e., X-direction) of the parallel portion 31. Therefore, the second bent portion 352 has the thickness in the Y-direction. The tip portion 353 stands vertically from the tip of the second bent portion 352 in the H-direction. The terminal 354 stands vertically from the tip of the tip portion 353 in the H-direction and is inserted in the receiving hole 61 of the printed circuit board 6.

As described above, according to the second embodiment, since the first bent portion 351 have the thickness in the X-direction, the first bent portion 351 can be easily deformed in the X-direction. Therefore, the first bent portion 351 can be deformed to absorb the relative displacement of the printed circuit board 6 with respect to the metal plate 2 and the busbar assembly 3 in the X-direction. Likewise, since the second bent portion 352 have the thickness in the Y-direction, the second bent portion 352 can be easily deformed in the Y-direction. Therefore, the second bent portion 352 can be deformed to absorb the relative displacement of the printed circuit board 6 with respect to the metal plate 2 and the busbar assembly 3 in the Y-direction.

In this way, like the bent portion 32 of the first embodiment, the bent portion 35 can reduce the thermal stress applied to the solder joints in the surface direction of the printed circuit board 6 so that the solder joints can be protected from repeated thermal stress.

Further, as can be seen by comparing FIGS. 3, 7, in the developed shape, the left ends of the parallel portions 31 are aligned in the X-direction. Therefore, the busbar bases can be collectively fixed to the metal plate 2, before the busbar bases are separated from each other by cutting tie-bars 320. In such an approach, the electronic device mounting structure can be easily made. Also, yield ratio of a material (i.e., metal plate) of the busbar assembly 3 is improved.

### Third Embodiment

An electronic mounting structure according to a third embodiment of the present invention is described below with reference to FIG. 10. A difference between the first and third embodiments is as follows.

FIG. 10 illustrates a developed shape of a bent portion 36 of each busbar 3A, 3D. In the developed shape, each bent portion 36 has a first bent portion 361 extending to the left in the X-direction from the left end of the parallel portion 31, a second bent portion 362 extending to the left in the X-direction from a tip of the first bent portion 361, a third bent portion 363 located between the first and second bent portions 361, 362, a tip portion 364 extending obliquely from a tip of the second bent portion 362, and a terminal extending from a tip of the tip portion 364. For example, the third bent portion 363 has a triangular shape. Alternatively, the third bent portion 363 can have a trapezoid shape, or the like.

The busbars 3A, 3D are arranged parallel to each other. The tip portions 364 of the busbars 3A, 3D are connected together through tie-bars 360 so that the busbars 3A, 3D can be joined together. A broken line 365 represents a border between the parallel portion 31 and the first bent portion 361. A broken line 366 represents a border between first and third bent portions 361, 363. A broken line 367 represents a border between second and third bent portions 362, 363.

The bent portion 36 shown in FIG. 10 is bent along the broken lines 365-367. In the bent shape, the first bent portion 361 stands from the left end of the parallel portion 31 so that the first bent portion 361 can have the thickness in the Y-direction. The second bent portion 362 extends obliquely upward in the Y-direction so that the second bent portion 362 can have the thickness in the X-direction. The tip portion 364 stands vertically from the tip of the second bent portion 362 in the H-direction. The terminal stands vertically from the tip of the tip portion 364 in the H-direction and is inserted in the receiving hole 61 of the printed circuit board 6.

As described above, according to the third embodiment, since the first bent portion 361 have the thickness in the Y-direction, the first bent portion 361 can be easily deformed in the Y-direction. Therefore, the first bent portion 361 can be deformed to absorb the relative displacement of the printed circuit board 6 with respect to the metal plate 2 and the busbar assembly 3 in the Y-direction. Likewise, since the second bent portion 362 have the thickness in the X-direction, the second bent portion 362 can be easily deformed in the X-direction. Therefore, the second bent portion 362 can be deformed to absorb the relative displacement of the printed circuit board 6 with respect to the metal plate 2 and the busbar assembly 3 in the X-direction.

In this way, like the bent portion 32 of the first embodiment, the bent portion 36 can reduce the thermal stress applied to the solder joints in the surface direction of the printed circuit board 6 so that the solder joints can be protected from repeated thermal stress.

Further, as can be seen from FIG. 10, the developed bent portion 36 is substantially located in an extension area of the parallel portion 31. Therefore, the yield ratio of the material of the busbar assembly 3 is improved. Also, since adjacent busbars can be arranged close to each other, the busbar assembly 3 can achieve high-density. Accordingly, the mounting structure can be reduced in size.

### Fourth Embodiment

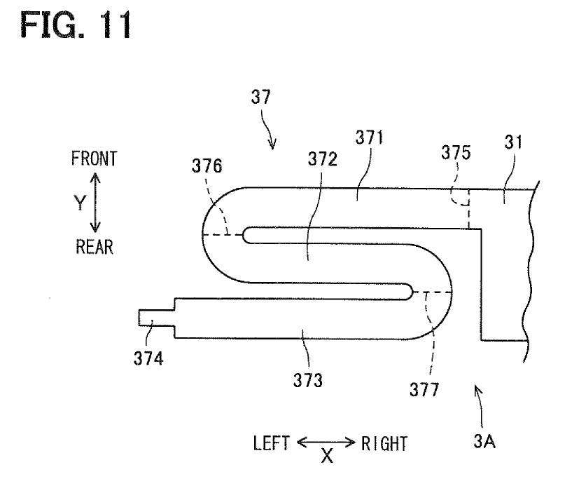

An electronic mounting structure according to a fourth embodiment of the present invention is described below with reference to FIG. 11A difference between the first and fourth embodiments is as follows.

FIG. 11 illustrates a developed shape of a bent portion 37 of a busbar 3A. In the developed shape, the bent portion 37 has a first bent portion 371 extending to the left in the X-direction from the left end of the parallel portion 31, a second bent portion 372 extending to the right in the X-direction from a tip of the first bent portion 371, a third bent portion 373 extending to the left in the X-direction from a tip of the second bent portion 372, a terminal 374 extending to the left in the X-direction from a tip of the third bent portion 373. Thus, as can been seen from FIG. 11, the bent portion 37 has a sinuous shape. The

A broken line 375 represents a border between the parallel portion 31 and the first bent portion 371. A broken line 376 represents a border between first and second bent portions 371, 372. A broken line 377 represents a border between second and third bent portions 372, 373. The bent portion 37 shown in FIG. 11 is bent along the broken lines 375-377. The broken line 375 extends in the Y-direction, and the broken lines 376, 377 extend in the X-direction. The bent portion 37 shown in FIG. 11 is bent along the broken lines 375-377 at a right angle.

In the bent shape, the first bent portion 371 stands at a right angle from the left end of the parallel portion 31 so that the first bent portion 371 can have the thickness in the X-direction. The second bent portion 372 extends downward from the tip of the first bent portion 371 so that the second bent portion 372 can have the thickness in the Y-direction. The third bent portion 373 extends upward from the tip of the second bent portion 372 so that the third bent portion 373 can have the thickness in the X-direction.

As described above, according to the fourth embodiment, since each the first and third bent portions 371, 373 has the thickness in the X-direction, each the first and third bent portions 371, 373 can be easily deformed in the X-direction. Therefore, each the first and third bent portions 371, 373 can be deformed to absorb the relative displacement of the printed circuit board 6 with respect to the metal plate 2 and the busbar assembly 3 in the Y-direction. Likewise, since the second bent portion 372 has the thickness in the Y-direction, the second bent portion 372 can be easily deformed in the Y-direction. Therefore, the second bent portion 372 can be deformed to absorb the relative displacement of the printed circuit board 6 with respect to the metal plate 2 and the busbar assembly 3 in the Y-direction.

In this way, like the bent portion 32 of the first embodiment, the bent portion 37 can reduce the thermal stress applied to the solder joints in the surface direction of the printed circuit board 6 so that the solder joints can be protected from repeated thermal stress.

Further, as can be seen from FIG. 11, the developed bent portion 37 is substantially located in an extension area of the parallel portion 31. Therefore, the yield ratio of the material of the busbar assembly 3 is improved. Also, since adjacent busbars can be arranged close to each other, the busbar assembly 3 can achieve high-density. Accordingly, the mounting structure can be reduced in size.

### MODIFICATIONS

The embodiments described above may be modified in various ways. For example, the term “substantially” can have a deviation of from plus 30 degrees to minus 30 degrees.

Such changes and modifications are to be understood as being within the scope of the present invention as defined by the appended claims.

What is claimed is:

1. An electronic device mounting structure comprising:
a printed circuit board;
a busbar including a parallel portion extending parallel to the printed circuit board and a bent portion extending from a first end of the parallel portion toward the printed circuit board, the parallel portion having a length in a first direction and a width in a second direction perpendicular to the first direction;
an electronic device fixed to the busbar and having a terminal soldered to a second end of the parallel portion of the busbar; and
a metal plate on which the busbar is fixed such that the metal plate and the busbar are electrically insulated from each other, the metal plate having a linear expansion coefficient greater than or equal to a linear expansion coefficient of the busbar,
wherein the bent portion of the busbar includes a first bent portion extending from the parallel portion, a second bent portion extending from the first bent portion, and a tip portion extending from the second bent portion,
wherein the first bent portion has a thickness substantially in the first direction,
wherein the second bent portion has a thickness substantially in the second direction, and
wherein the tip portion stands substantially at a right angle with respect to the second bent portion and is soldered to the printed circuit board.

2. The electronic device mounting structure according to claim 1,
wherein the first bent portion includes a first portion standing substantially at a right angle with respect to the parallel portion and a second portion extending from the first portion in the second direction, and
wherein the second bent portion extends from the second portion of the first bent portion in the first direction.

3. The electronic device mounting structure according to claim 1,
wherein the first bent portion stands obliquely with respect to the parallel portion and extends in the second direction, and
wherein the second bent portion stands obliquely with respect to the first bent portion and extends in the first direction.

4. The electronic device mounting structure according to claim 1,
wherein the first bent portion is bent along a line substantially parallel to the parallel portion to have a sinuous shape and extends parallel to the parallel portion, and
wherein the second bent portion stands obliquely with respect to the first bent portion and extends in the second direction.

5. A method of making the electronic device mounting structure of claim 1, comprising:
forming a plurality of busbar bases connected together through tie-bars from a metal sheet by press punching, the plurality of busbar bases including a plurality of parallel portions arranged parallel to each other and a plurality of developed bent portions, each developed bent portion being joined to a corresponding parallel portion;
separating the plurality of busbar bases from each other by cutting the tie-bars; and
bending the developed bent portion of the separated busbar base to form the first and second bent portions.
